(19) United States
(12) Patent Application Publication
(10) Pub. No.: US 2011/0272730 A1
(43) Pub. Date: Nov. 10, 2011

(54) LIGHT EMITTING DEVICE

(75) Inventors: Duk-Kyu BAE, Yongin-si (KR); Yong-Sung JIN, Seongnam-si (KR); Jae-Ho SONG, Yongin-si (KR); In-Sung CHO, Gunpo-si (KR)

(73) Assignee: THELEDS CO., LTD., Gwangju (KR)

(21) Appl. No.: 13/099,676

(22) Filed: May 3, 2011

(30) Foreign Application Priority Data
May 6, 2010 (KR) 10-2010-0042512
May 6, 2010 (KR) 10-2010-0042514

(51) Int. Cl. H01L 33/00

(52) U.S. Cl. 257/99; 257/E33.001

(57) ABSTRACT

A light emitting device having an electrode structure in which resistance to electrostatic discharge (ESD) is increased, the static electricity is efficiently dispersed and a current concentration phenomenon is prevented, the light emitting device including: a substrate; a first conductivity type semiconductor layer, an active layer, a second conductivity type semiconductor layer opposite to the first conductivity type semiconductor layer that are sequentially formed on the substrate; a first conductivity type electrode pad formed on the first conductivity type semiconductor layer; a second conductivity type electrode pad formed on the second conductivity type semiconductor layer; a first auxiliary electrode formed on the second conductivity type semiconductor layer to extend in one direction and having one end connected to the second conductivity type electrode pad and the other end formed in an opposite direction to a direction toward the first conductivity type electrode pad; and a second auxiliary electrode formed on the second conductivity type semiconductor layer to extend in one direction and including a main arm having one end connected to the second conductivity type electrode pad and the other end formed in a direction toward the first conductivity type electrode pad and a plurality of second auxiliary sub-electrodes extending from the other end of the main arm, wherein a direction in which an end of each of the second auxiliary sub-electrodes extends, is not toward the first conductivity electrode pad.

### CROSS-REFERENCE TO RELATED PATENT APPLICATION

This application claims the benefits of Korean Patent Application No. 10-2010-0042512 and No. 10-2010-0042514, filed on May 6, 2010, in the Korean Intellectual Property Office, the disclosures of which are incorporated herein in their entirety by reference.

### BACKGROUND OF THE INVENTION

1. Field of the Invention

The present invention relates to a light emitting device, and more particularly, to a light emitting device having an electrode structure in which resistance to electrostatic discharge (ESD) is increased, the static electricity is efficiently dispersed and a current concentration phenomenon is prevented.

2. Description of the Related Art

Light emitting devices, such as light emitting diodes (LEDs) or laser diodes (LDs), are devices for converting current into light. Light emitting devices each include an active layer formed of a semiconductor material interposed between a p-type semiconductor layer and an n-type semiconductor layer. When a driving current is applied to both ends of the p-type semiconductor layer and the n-type semiconductor layer, electrons and holes are injected into the active layer from the p-type semiconductor layer and the n-type semiconductor layer. The injected electrons and holes are recombined with one another in the active layer so that light can be generated.

Generally, semiconductor light emitting devices are manufactured of a nitride-based III-V-group semiconductor compound having the empirical formula of AlₓIn_{y}Ga_{(1-x-y)}N (where, 0≦x≦1, 0≦y≦1, 0≦x+y≦1). Such semiconductor light emitting devices are devices that emit single-wavelength light (ultraviolet rays or green light), in particular, blue light. However, since the nitride-based III-V-group semiconductor compound is manufactured using an insulating substrate, such as a sapphire substrate, a silicon carbide (SiC) substrate or the like that satisfies a lattice match condition for crystal growth, the nitride-based III-V-group semiconductor compound has a planar structure in which two electrodes (p-type electrode and n-type electrode) formed on the p-type semiconductor layer and the n-type semiconductor layer are nearly planarly arranged on a top surface of a light emitting structure so as to apply the driving current to both ends of the p-type semiconductor layer and the n-type semiconductor layer.

High luminance is required to use nitride-based semiconductor light emitting devices having the planar structure as a light source, and a structure for improving luminous efficiency by uniformly dispersing current is required for achieving high luminance. However, in such nitride-based semiconductor light emitting devices having the planar structure, the flow of current is not uniformly distributed in the entire light emitting region, compared to nitride-based semiconductor light emitting devices having a vertical structure in which two electrodes are perpendicularly arranged on top and bottom surfaces of a light emitting structure. Thus, the nitride-based semiconductor light emitting devices having the planar structure have lower luminous efficiency than that of the nitride-based semiconductor light emitting devices having the vertical structure.

FIG. 1 is a cross-sectional view of a nitride-based semiconductor light emitting device 1 according to the related art. The nitride-based semiconductor light emitting device 1 is formed by sequentially stacking an n-type semiconductor layer 3, an active layer 4, a p-type semiconductor layer 5, and a transparent electrode 6 on a sapphire substrate 2 having an insulation property. An n-type electrode 11 is formed on the n-type semiconductor layer 3 exposed after portions of the active layer 4, the p-type semiconductor layer 5, and the transparent electrode 6 are mesa etched. A p-type electrode 15 is formed on the transparent electrode 6.

FIG. 2 is a plan view of an electrode structure of the nitride-based semiconductor light emitting device 1 according to the related art illustrated in FIG. 1.

Referring to FIG. 2, a p-type electrode pad 16 that is part of the p-type electrode 15 and that is a region in which wire bonding will be performed, is formed at a one-side edge of an upper portion of the transparent electrode 6. An n-type electrode pad 12 that is part of the n-type electrode 11 and that is a region in which wire bonding will be performed, is formed at the other-side edge of the upper portion of the transparent electrode 6 facing the p-type electrode pad 16, i.e., on the n-type semiconductor layer 3.

When current flows through the p-type electrode pad 16 and the n-type electrode pad 12, the current flows through the active layer 4 so that light can be generated. However, since the p-type electrode pad 16 and the n-type electrode pad 12 are generally separated from each other at a long distance, current densities of regions of the nitride-based semiconductor light emitting device 1 are greatly different from one another. Since luminous efficiency is high and the magnitude of a driving voltage can be reduced when the current densities of the regions of the nitride-based semiconductor light emitting device 1 are uniform, the p-type electrode 15 includes two p-type auxiliary electrodes 17 and 18 so as to make the current densities of the regions of the nitride-based semiconductor light emitting device 1 uniform. In other words, as illustrated in FIG. 2, the p-type auxiliary electrodes 17 and 18 are formed on the p-type electrode pad 16 and are shaped as extending from both sides of the p-type electrode pad 16.

However, since a GaN-based compound semiconductor that is used to form a light emitting device is grown on a sapphire substrate having a different lattice constant from that of the GaN-based compound semiconductor, there are crystal defects of about 10⁸ to 10¹⁰, such as dislocation caused by lattice mismatch. The crystal defects affect the light emitting device adversely due to the static electricity generated in equipment for manufacturing a light emitting device and workers. In particular, due to a phenomenon that current is concentrated on the shortest path of a p-type electrode and an n-type electrode, electrostatic discharge characteristics of the light emitting device are further deteriorated. In the electrode structure of FIG. 2, the light emitting device may be severely damaged due to electrostatic discharge generated at the end of the p-type auxiliary electrode 17 facing the n-type electrode pad 12. Since current is concentrated on the end of the p-type auxiliary electrode 17, heat is concentratively generated in the end of the p-type auxiliary electrode 17 so that the reliability of the light emitting device is lowered.

When the size of the light emitting device is increased, the flow of current is not smooth so that luminous efficiency is lowered. In addition, when the size of an electrode is increased, the flow of current may be improved but a light emitting area is reduced and luminous efficiency is lowered. Thus, an electrode structure of the light emitting device needs to be improved so as to prevent the current concentration phenomenon and to efficiently disperse the static electricity.

### SUMMARY OF THE INVENTION

The present invention provides a light emitting device having an electrode structure in which resistance to electrostatic discharge is increased, the static electricity is efficiently dispersed and a current concentration phenomenon is prevented.

According to an aspect of the present invention, there is provided a light emitting device including: a substrate; a first conductivity type semiconductor layer, an active layer, a second conductivity type semiconductor layer opposite to the first conductivity type semiconductor layer that are sequentially formed on the substrate; a first conductivity type electrode pad formed on the first conductivity type semiconductor layer; a second conductivity type electrode pad formed on the second conductivity type semiconductor layer; a first auxiliary electrode formed on the second conductivity type semiconductor layer to extend in one direction and having one end connected to the second conductivity type electrode pad and the other end formed in an opposite direction to a direction toward the first conductivity type electrode pad; and a second auxiliary electrode formed on the second conductivity type semiconductor layer to extend in one direction and including a main arm having one end connected to the second conductivity type electrode pad and the other end formed in a direction toward the first conductivity type electrode pad and a plurality of second auxiliary sub-electrodes extending from the other end of the main arm, wherein a direction in which an end of each of the second auxiliary sub-electrodes extends, is not toward the first conductivity electrode pad.

The second auxiliary sub-electrodes may be symmetrical to each other based on a direction in which the main arm is formed.

The second auxiliary electrode may include two second auxiliary sub-electrodes formed symmetrical to each other based on a direction in which the main arm is formed.

Each of the second auxiliary sub-electrodes may extend from the other end of the main arm so as to form an arc shape. The second auxiliary sub-electrodes may be formed in such a way that a direction in which an end of each of the second auxiliary sub-electrodes extends, is perpendicular to a direction from the second conductivity type electrode pad to the first conductivity type electrode pad. The second auxiliary sub-electrodes may be formed in such a way that a direction in which an end of each of the second auxiliary sub-electrodes extends, is toward the second conductivity type electrode pad. The second auxiliary sub-electrodes may be formed in such a way that a direction in which an end of each of the second auxiliary sub-electrodes extends, is a direction between a direction from the second conductivity type electrode pad to the first conductivity type electrode pad and a direction perpendicular to the direction from the second conductivity type electrode pad to the first conductivity type electrode pad.

According to another embodiment of the present invention, there is provided a light emitting device including: a substrate; a first conductivity type semiconductor layer, an active layer, a second conductivity type semiconductor layer opposite to the first conductivity type semiconductor layer that are sequentially formed on the substrate; a first conductivity type electrode pad formed on the first conductivity type semiconductor layer; a second conductivity type electrode pad formed on the second conductivity type semiconductor layer; a first auxiliary electrode formed on the second conductivity type semiconductor layer to extend in one direction and having one end connected to the second conductivity type electrode pad and the other end formed in an opposite direction to a direction toward the first conductivity type electrode pad; and a second auxiliary electrode formed on the second conductivity type semiconductor layer to extend in one direction and including a main arm having one end connected to the second conductivity type electrode pad and the other end formed in a direction toward the first conductivity type electrode pad and an extension portion shaped as a dot formed at the other end of the main arm, wherein a width of the extension portion defined as a maximum length in a direction parallel to a direction perpendicular to a direction in which the main arm is formed, is greater than an average line width of the main arm.

The width of the extension portion may be set to a range of 1.5 to 5 times of the average line width of the main arm.

A top surface of the extension portion may be shaped as one of a circle, an oval, a semicircle, a polygon, and a figure having a plurality of protrusions formed therein.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a semiconductor light emitting device according to the related art, and

FIG. 2 is a plan view thereof;

FIG. 3 is a cross-sectional view of a light emitting device according to an embodiment of the present invention; and

FIGS. 4 through 17 are plan views of structures of semiconductor light emitting devices according to embodiments of the present invention.

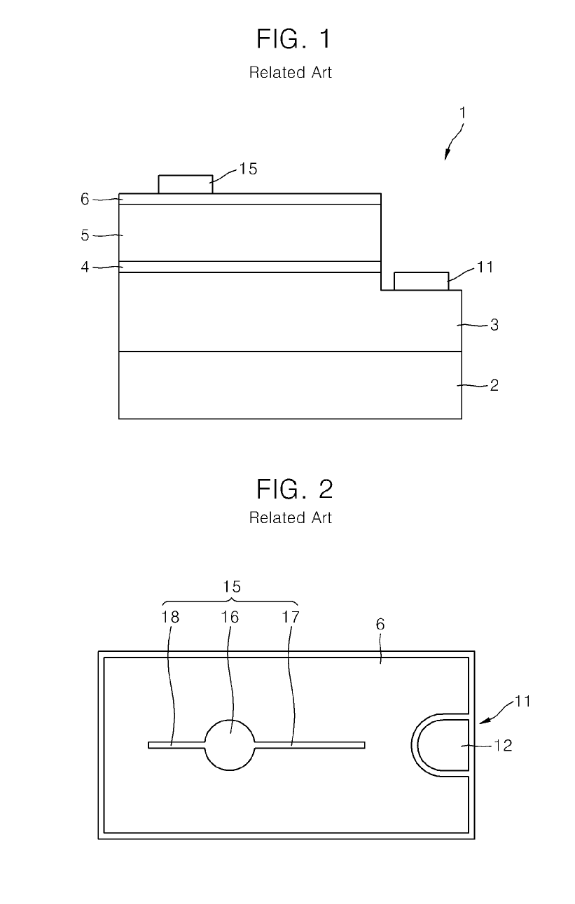

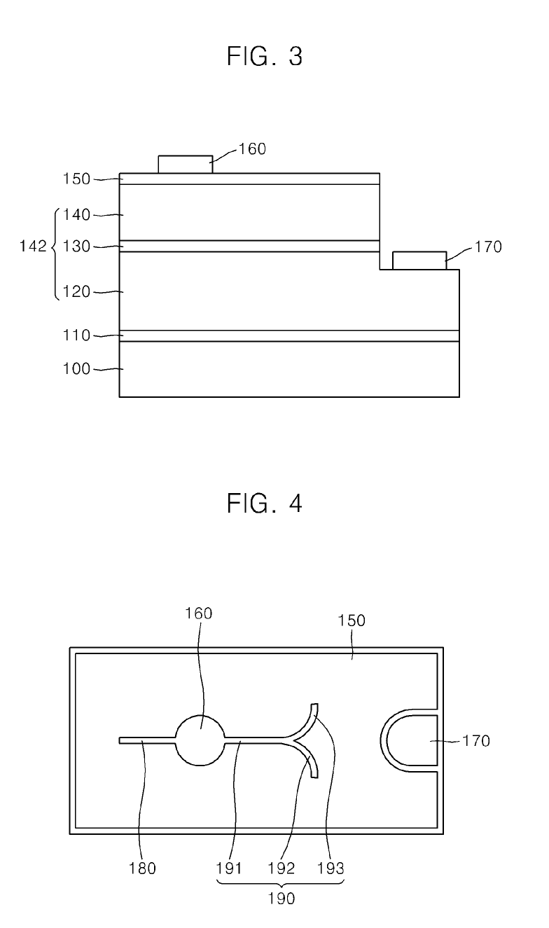

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Besides, in the following embodiments, a first conductivity type is an n-type and a second conductivity type contrary to the first conductivity type is a p-type, however, vise versa is also possible. Like reference numerals in the drawings denote like elements, and thus their description will be omitted.

The structure of a semiconductor light emitting device according to exemplary embodiments of the present invention will now be described with reference to FIGS. 3 through 17.

FIG. 3 is a cross-sectional view of a light emitting device according to an embodiment of the present invention, and FIGS. 4 through 17 are plan views of structures of semiconductor light emitting devices according to exemplary embodiments of the present invention.

Referring to FIGS. 3 through 17, each of the semiconductor light emitting devices according to exemplary embodiments of the present invention includes a light emitting structure including an epilayer 142 including an n-type semiconductor layer 120, an active layer 130, and a p-type semiconductor layer 140, which are sequentially stacked above a substrate 100. As illustrated in FIGS. 3 through 17, each semiconductor light emitting device may further include at least one of a conductive layer formed between the substrate 100 and the n-type semiconductor layer 120 and a conductive layer formed between the p-type semiconductor layer 140 and a p-type electrode 160. In the present embodiment, a conductive layer formed between the substrate 100 and the n-type semiconductor layer 120 is a buffer layer 110, and a conductive layer formed between the p-type semiconductor layer 140 and the p-type electrode 160 is a transparent electrode 150.

The substrate 100 is suitable for growing nitride semiconductor single crystal and may be formed of a transparent material including sapphire and may be formed of zinc oxide (ZnO), gallium nitride (GaN), silicon carbide (SiC), aluminum nitride (AlN) or the like, as well as sapphire.

The buffer layer 110 is a layer for improving lattice match between the buffer layer 110 and the substrate 100 before the n-type semiconductor layer 120 is grown on the substrate 100. The buffer layer may be formed of AlN/GaN. The buffer layer 110 is not an essential element of the semiconductor light emitting device according to the present embodiment and may be omitted according to characteristics and process conditions of the semiconductor light emitting device.

The n-type semiconductor layer 120, the active layer 130, and the p-type semiconductor layer 140 of the epilayer 142 may be formed of a semiconductor material having the empirical formula In_{X}Al_{Y}Ga_{1-X-Y}N (where, 0≦X≦1, 0≦Y≦1, 0≦X+Y≦1). More specifically, the n-type semiconductor layer 120 may be formed of a GaN layer or a GaN/AlGaN layer having a doped n-type impurity. The n-type impurity includes silicon (Si), germanium (Ge), tin (Sn) or the like and may be usually Si. In addition, the p-type semiconductor layer 140 may be formed of a GaN layer or a GaN/AlGaN layer having a doped p-type impurity, and the doped p-type impurity may be magnesium (Mg), zinc (Zn), beryllium (Be) or the like and may be usually Mg. The active layer 130 acts as a layer for generating and emitting light. The active layer 130 is formed by forming an InGaN layer as a well, forming a GaN layer as a wall layer and thereby forming a multi-quantum well. The active layer 130 may have one quantum well layer or a double hetero structure. The buffer layer 110, the n-type semiconductor layer 120, the active layer 130, and the p-type semiconductor layer 140 are formed by performing a deposition process, such as metal organic chemical vapor deposition (MOCVD), molecular beam epitaxy (MBE) or hydride vapor phase epitaxial (HVPE) deposition.

If transmittance of the transparent electrode 150 relative to a light emitting wavelength of the semiconductor light emitting device is high, the transparent electrode 150 may be formed of a metal thin layer having high conductivity and low contact resistance, as well as a conductive metal oxide, such as an indium tin oxide (ITO). The transparent electrode 150 is also not an essential element of the semiconductor light emitting device according to the present embodiment and may be omitted according to characteristics and process conditions of the semiconductor light emitting device.

Part of the epilayer 142, e.g., part of the active layer 130, the p-type semiconductor layer 140, and the transparent electrode 150 is removed by mesa etching so that part of a top surface of the n-type semiconductor layer 120 formed on the bottom surface of the epilayer 142 is exposed. In this regard, an edge of the active layer 130 may be formed toward the center of the semiconductor light emitting device while being separated from all edges of the n-type semiconductor layer 120 by a predetermined distance. This is because, when a nitride-based semiconductor light emitting device is driven, the flow of current is uniformly dispersed into the entire surface of the active layer 130, i.e., the entire light emitting area. The transparent electrode 150 may be also formed toward the center of the semiconductor light emitting device while being separated from all edges of the p-type semiconductor layer 140 by a predetermined distance.

A p-type electrode pad 160 is formed on the transparent electrode 150. A n-type electrode pad 170 is formed on the n-type semiconductor layer 120 exposed as the result of mesa etching part of the active layer 130, the p-type semiconductor layer 140, and the transparent electrode 150. The p-type electrode pad 160 is formed at one side of the center of the semiconductor light emitting device, and the n-type electrode pad 170 is formed at the other side of the center of the semiconductor light emitting device. A first auxiliary electrode 180 and second auxiliary electrodes 190 and 190′ that are connected to the p-type electrode pad 160 are formed on the transparent electrode 150.

The first auxiliary electrode 180 is shaped as extending in one direction. One end of the first auxiliary electrode 180 is connected to the p-type electrode pad 160, and the first auxiliary electrode 180 is formed in such a way that the other end of the first auxiliary electrode 180 is in an opposite direction to a direction toward the n-type electrode pad 170.

Referring to FIGS. 4 through 9, the second auxiliary electrode 190 includes a main arm 191 and a plurality of second auxiliary sub-electrodes 192 and 193. Referring to FIGS. 10 through 17, the second auxiliary electrode 190′ includes a main arm 191 and an extension portion 195. The first auxiliary electrode 180 and the main arm 191 may be formed in the same straight line, as illustrated in FIGS. 4 through 17. The main arm 191 is formed on the transparent electrode 150 and is shaped as extending in one direction. The main arm 191 is formed in such a way that one end of the main arm 191 is connected to the p-type electrode pad 160 and the other end of the main arm 191 is in a direction toward the n-type electrode pad 170.

As illustrated in FIGS. 4 through 9, the second auxiliary sub-electrodes 192 and 193 extend from the other end of the main arm 191. The second auxiliary sub-electrodes 192 and 193 are formed in such a way that a direction in which an end of each of the second auxiliary sub-electrodes 192 and 193 extends, is not a direction toward the n-type electrode pad 170. As illustrated in FIGS. 4 through 9, the second auxiliary electrode 190 may include two second auxiliary sub-electrodes 192 and 193, and the two second auxiliary sub-electrodes 192 and 193 may be formed symmetrical to each other in a direction in which the main arm 191 is formed.

In FIGS. 4 through 9, there are two second auxiliary sub-electrodes. However, the present invention is not limited thereto, and the number of second auxiliary sub-electrodes may be two or more. Even in this case, the second auxiliary sub-electrodes may be formed symmetrical to each other in the direction in which the main arm 191 is formed.

Referring to FIGS. 10 through 17, the extension portion 195 is shaped as a dot at the other end of the main arm 191. The width of the extension portion 195 is greater than the average line width of the main arm 191. In this regard, the width of the extension portion 195 is defined as the maximum length in a direction parallel to a direction perpendicular to the direction in which the main arm 191 is formed. The average line width of the main arm 191 is the average of widths of the main arm 191. A top surface of the extension portion 195 may be shaped as one of a circle, an oval, a semicircle, a polygon, and a figure having a plurality of protrusions formed therein.

In this regard, as the width of the extension portion 195 increases, a static electricity-dispersing degree increases. However, due to an increase in the entire electrode area, luminous efficiency is lowered. Thus, the width of the extension portion 195 may be set to the range of 1.5 to 5 times of the average line width of the main arm 191. When the extension portion 195 is employed in the second auxiliary electrode 190′ in such a manner, luminous efficiency is hardly changed, and an electrostatic discharge (ESD) yield may increase from 55.7% to 95.9%.

When the semiconductor light emitting device has the electrode structure illustrated in FIGS. 4 through 17, the static electricity may be efficiently dispersed, and resistance to electrostatic discharge may be increased. Thus, the reliability and yield of the semiconductor light emitting device are improved by improving a problem relating to electrostatic discharge that is the cause of breakdown of the semiconductor light emitting device. Since a current concentration phenomenon between an auxiliary electrode and an n-type electrode pad can be alleviated, current is uniformly dispersed into the semiconductor light emitting device. In addition, a Zener diode does not need to be additionally connected to the semiconductor light emitting device so as to prevent current from flowing reversely so that manufacturing costs and time required for manufacturing the semiconductor light emitting device are reduced and productivity thereof is improved.

14 embodiments illustrated in FIGS. 4 through 17 are exemplary embodiments of second auxiliary electrodes that may disperse the static electricity efficiently.

In an embodiment (FIG. 4), each of two second auxiliary sub-electrodes 192 and 193 extends from an end of the main arm 191 so as to form an arc shape, and the two second auxiliary sub-electrodes 192 and 193 are symmetrical to each other based on the main arm 191. The second auxiliary sub-electrodes 192 and 193 are formed in such a way that a direction in which an end of each of the second auxiliary sub-electrodes 192 and 193 extends, may be perpendicular to a direction from the p-type electrode pad 160 to the n-type electrode pad 170.

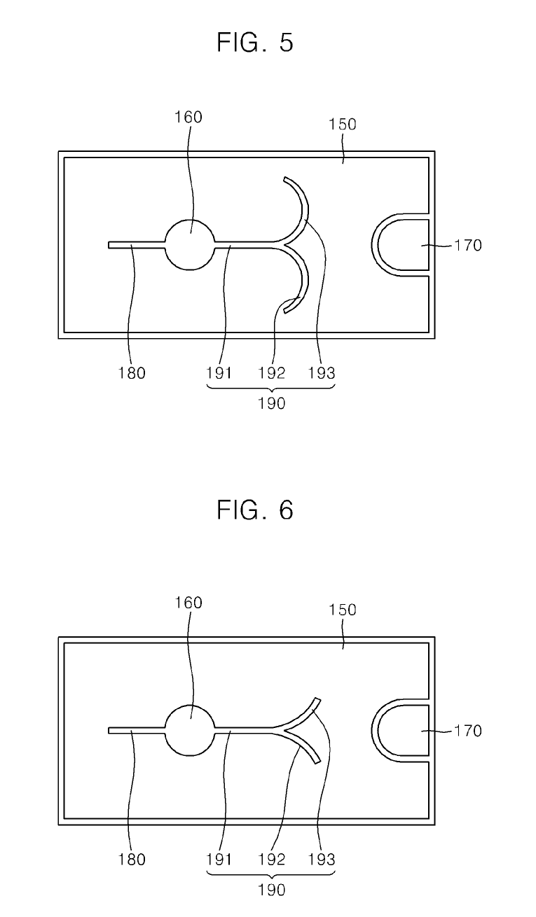

In another embodiment (FIG. 5), each of the two second auxiliary sub-electrodes 192 and 193 extends from an end of the main arm 191 so as to form an arc shape, and the two second auxiliary sub-electrodes 192 and 193 are symmetrical to each other based on a main arm 191. The second auxiliary sub-electrodes 192 and 193 are formed in such a way that the direction in which the end of each of the second auxiliary sub-electrodes 192 and 193 extends, may be toward the p-type electrode pad 160. Each of the two second auxiliary sub-electrodes 192 and 193 illustrated in FIG. 5 is shaped as a sickle bent at an angle of 90° or more.

In another embodiment (FIG. 6), each of the two second auxiliary sub-electrodes 192 and 193 extends from the end of the main arm 191 so as to form an arc shape, and the two second auxiliary sub-electrodes 192 and 193 are symmetrical to each other based on the main arm 191. The second auxiliary sub-electrodes 192 and 193 are formed in such a way that the direction in which the end of each of the second auxiliary sub-electrodes 192 and 193 extends, may be a direction between a direction from the p-type electrode pad 160 to the n-type electrode pad 170 and a direction perpendicular to the direction from the p-type electrode pad 160 to the n-type electrode pad 170. Each of the two second auxiliary sub-electrodes 192 and 193 illustrated in FIG. 6 is shaped as sprout.

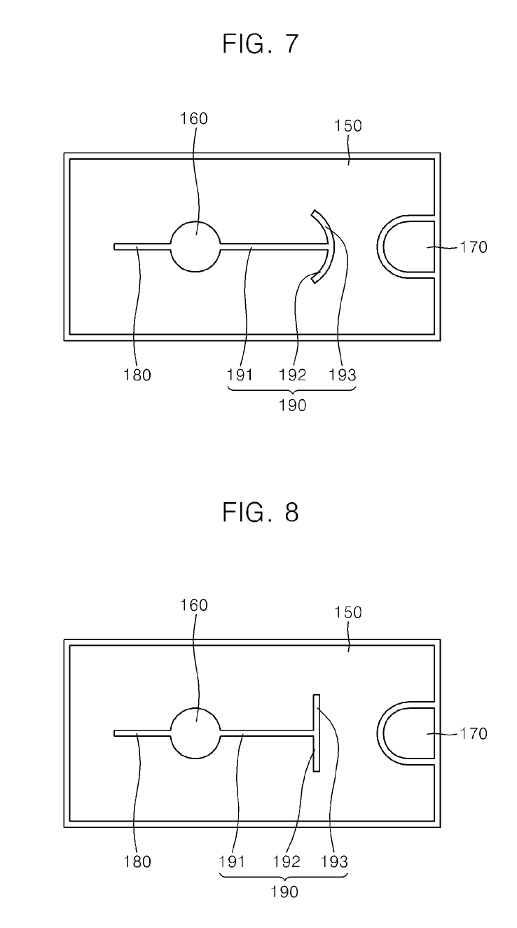

In another embodiment (FIG. 7), the two second auxiliary sub-electrodes 192 and 193 extend from the end of the main arm 191 so as to form an arc shape and are symmetrical to each other based on the main arm 191. The second auxiliary sub-electrodes 192 and 193 are formed in such a way that the direction in which the end of each of the second auxiliary sub-electrodes 192 and 193 extends, may be toward the p-type electrode pad 160. Each of the two second auxiliary sub-electrodes 192 and 193 illustrated in FIG. 7 is shaped as a semicircle.

In another embodiment (FIG. 8), each of the two second auxiliary sub-electrodes 192 and 193 extends from the end of the main arm 191 so as to form a bar shape extending in one direction, and the two second auxiliary sub-electrodes 192 and 193 are symmetrical to each other based on the main arm 191. The second auxiliary sub-electrodes 192 and 193 are formed in such a way that the direction in which the end of each of the second auxiliary sub-electrodes 192 and 193 extends, may be perpendicular to a direction from the p-type electrode pad 160 to the n-type electrode pad 170. Each of the two second auxiliary sub-electrodes 192 and 193 illustrated in FIG. 8 is shaped as a straight line.

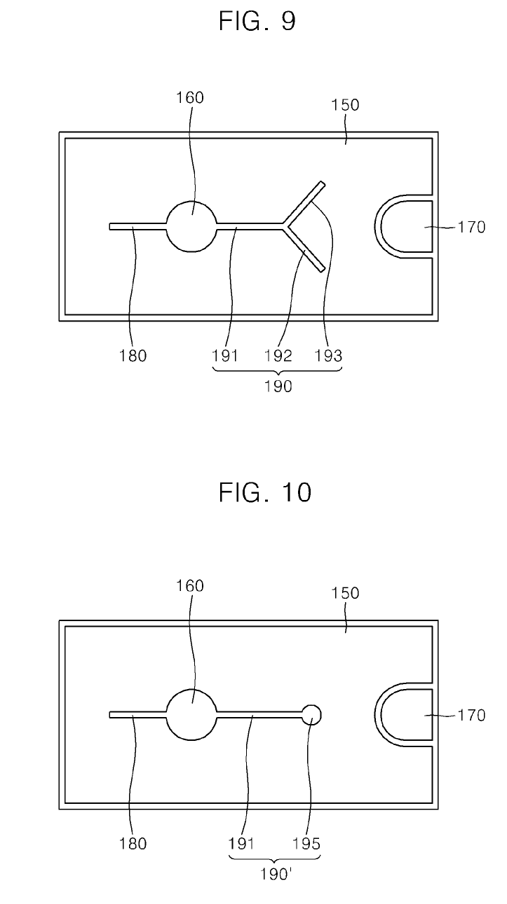

In another embodiment (FIG. 9), each of the two second auxiliary sub-electrodes 192 and 193 extends from the end of the main arm 191 so as to form a bar shape extending in one direction, and the two second auxiliary sub-electrodes 192 and 193 are symmetrical to each other based on the main arm 191. The second auxiliary sub-electrodes 192 and 193 are formed in such a way that the direction in which the end of each of the second auxiliary sub-electrodes 192 and 193 extends, may be a direction between a direction from the p-type electrode pad 160 to the n-type electrode pad 170 and a direction perpendicular to the direction from the p-type electrode pad 160 to the n-type electrode pad 170. Each of the two second auxiliary sub-electrodes 192 and 193 illustrated in FIG. 9 is shaped as V.

Regardless of the shape of each of the second auxiliary sub-electrodes 192 and 193, as the second auxiliary sub-electrodes 192 and 193 are employed in the second auxiliary electrode 190, the static electricity may be efficiently dispersed.

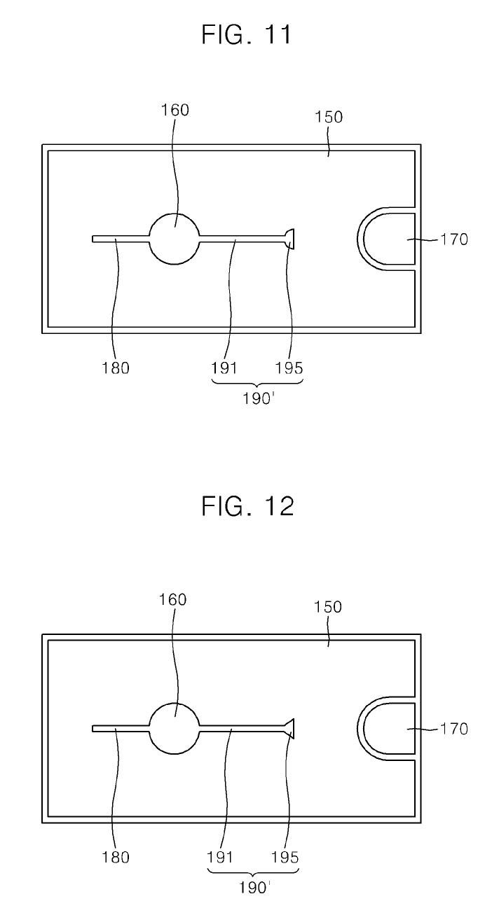

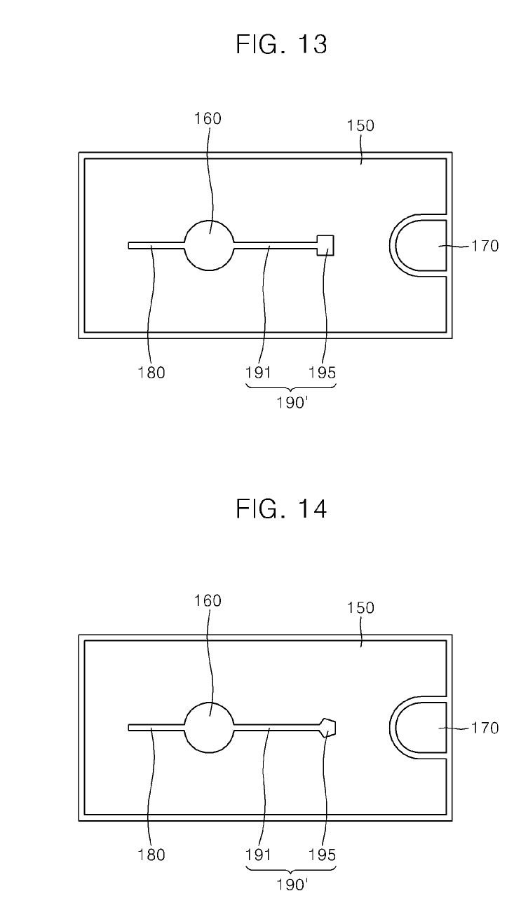

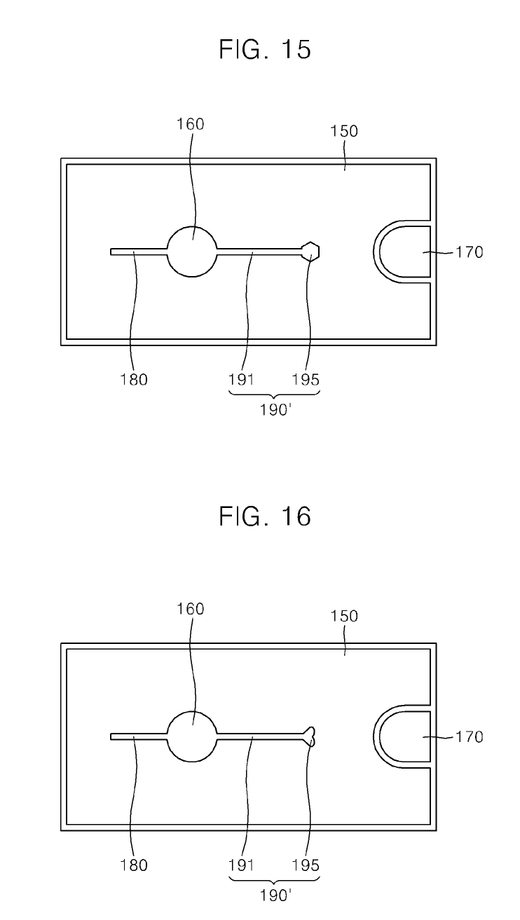

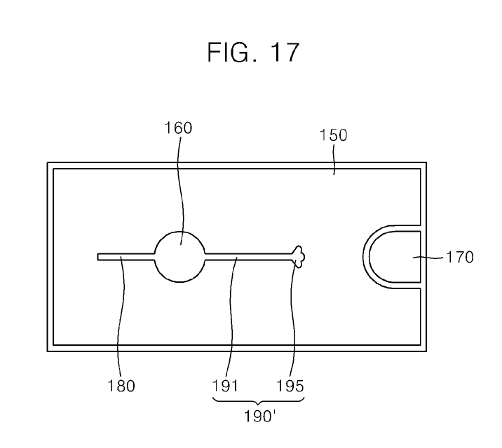

Another embodiment (FIG. 10) is directed to a case where the top surface of the extension portion 195 is shaped as a circle. Another embodiment (FIG. 11) is directed to a case where the top surface of the extension portion 195 is shaped as a semicircle. Another embodiment (FIG. 12) is directed to a case where the top surface of the extension portion 195 is shaped as an equilateral triangle. Another embodiment (FIG. 13) is directed to a case where the top surface of the extension portion 195 is shaped as a square. Another embodiment (FIG. 14) is directed to a case where the top surface of the extension portion 195 is shaped as a regular pentagon. Another embodiment (FIG. 15) is directed to a case where the top surface of the extension portion 195 is shaped as a regular hexagon. Another embodiment (FIG. 16) is directed to a case where the top surface of the extension portion 195 is shaped as a figure having two protrusions formed therein (a heart shape). Another embodiment (FIG. 17) is directed to a case where the top surface of the extension portion 195 is shaped as a figure having three protrusions formed therein. Like in FIGS. 16 and 17, when the top surface of the extension portion 195 is shaped as a figure having protrusions formed therein, the protrusions may protrude toward the n-type electrode pad 170.

Regardless of the shape of the top surface of the extension portion 195, as the extension portion 195 is employed in the second auxiliary electrode 190′, the static electricity may be efficiently dispersed.

As described above, when a light emitting device has an electrode structure according to the present invention, the static electricity can be efficiently dispersed, and resistance to electrostatic discharge can be increased. As a result of evaluating resistance to electrostatic discharge, when a second auxiliary electrode is formed like in the present invention, luminous efficiency is hardly changed, and an ESD yield can be increased from 57.9% to 89.8% when a forward voltage is applied to the light emitting device (an increase in ESD yield: 55.1%), and the ESD yield can be increased from 29.5% to 34.5% when a reverse voltage is applied to the light emitting device (an increase in ESD yield: 16.9%). When an extension portion is employed in the second auxiliary electrode like in the present invention, luminous efficiency is hardly changed, the ESD yield can be increased from 55.7% to 95.9%. In addition, since a current concentration phenomenon between the second auxiliary electrode and a first conductivity type electrode pad can be alleviated so that current can be uniformly dispersed into the light emitting device. Thus, the reliability and yield of the light emitting device are improved. Furthermore, a Zener diode does not need to be additionally connected to the light emitting device so as to prevent current from flowing reversely so that time required for manufacturing the light emitting device can be reduced and manufacturing costs can be reduced.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A light emitting device comprising:
a substrate;
a first conductivity type semiconductor layer, an active layer, a second conductivity type semiconductor layer opposite to the first conductivity type semiconductor layer that are sequentially formed on the substrate;
a first conductivity type electrode pad formed on the first conductivity type semiconductor layer;
a second conductivity type electrode pad formed on the second conductivity type semiconductor layer;
a first auxiliary electrode formed on the second conductivity type semiconductor layer to extend in one direction and having one end connected to the second conductivity type electrode pad and the other end formed in an opposite direction to a direction toward the first conductivity type electrode pad; and
a second auxiliary electrode formed on the second conductivity type semiconductor layer to extend in one direction and comprising a main arm having one end connected to the second conductivity type electrode pad and the other end formed in a direction toward the first conductivity type electrode pad and a plurality of second auxiliary sub-electrodes extending from the other end of the main arm,
wherein a direction in which an end of each of the second auxiliary sub-electrodes extends, is not toward the first conductivity electrode pad.

2. The light emitting device of claim 1, wherein the second auxiliary sub-electrodes are symmetrical to each other based on a direction in which the main arm is formed.

3. The light emitting device of claim 2, wherein the second auxiliary electrode comprises two second auxiliary sub-electrodes formed symmetrical to each other based on a direction in which the main arm is formed.

4. The light emitting device of claim 3, wherein each of the second auxiliary sub-electrodes extends from the other end of the main arm so as to form an arc shape.

5. The light emitting device of claim 4, wherein the second auxiliary sub-electrodes are formed in such a way that a direction in which an end of each of the second auxiliary sub-electrodes extends, is perpendicular to a direction from the second conductivity type electrode pad to the first conductivity type electrode pad.

6. The light emitting device of claim 4, wherein the second auxiliary sub-electrodes are formed in such a way that a direction in which an end of each of the second auxiliary sub-electrodes extends, is toward the second conductivity type electrode pad.

7. The light emitting device of claim 4, wherein the second auxiliary sub-electrodes are formed in such a way that a direction in which an end of each of the second auxiliary sub-electrodes extends, is a direction between a direction from the second conductivity type electrode pad to the first conductivity type electrode pad and a direction perpendicular to the direction from the second conductivity type electrode pad to the first conductivity type electrode pad.

8. The light emitting device of claim 3, wherein the two second auxiliary sub-electrodes extend from the other end of the main arm so as to form an arc shape.

9. The light emitting device of claim 8, wherein the second auxiliary sub-electrodes are formed in such a way that a direction in which an end of each of the second auxiliary sub-electrodes extends, is toward the second conductivity type electrode pad.

10. The light emitting device of claim 3, wherein each of the second auxiliary sub-electrodes extends from the other end of the main arm so as to extend in one direction.

11. The light emitting device of claim 10, wherein the second auxiliary sub-electrodes are formed in such a way that a direction in which the second auxiliary sub-electrodes are formed, is perpendicular to a direction from the second conductivity type electrode pad to the first conductivity type electrode pad.

12. The light emitting device of claim 10, wherein the second auxiliary sub-electrodes are formed in such a way that a direction in which the second auxiliary sub-electrodes are formed, is a direction between a direction from the second conductivity type electrode pad to the first conductivity type electrode pad and a direction perpendicular to the direction from the second conductivity type electrode pad to the first conductivity type electrode pad.

13. A light emitting device comprising:
a substrate;
a first conductivity type semiconductor layer, an active layer, a second conductivity type semiconductor layer opposite to the first conductivity type semiconductor layer that are sequentially formed on the substrate;
a first conductivity type electrode pad formed on the first conductivity type semiconductor layer;
a second conductivity type electrode pad formed on the second conductivity type semiconductor layer;
a first auxiliary electrode formed on the second conductivity type semiconductor layer to extend in one direction and having one end connected to the second conductivity type electrode pad and the other end formed in an opposite direction to a direction toward the first conductivity type electrode pad; and
a second auxiliary electrode formed on the second conductivity type semiconductor layer to extend in one direction and comprising a main arm having one end connected to the second conductivity type electrode pad and the other end formed in a direction toward the first conductivity type electrode pad and an extension portion shaped as a dot formed at the other end of the main arm,
wherein a width of the extension portion defined as a maximum length in a direction parallel to a direction perpendicular to a direction in which the main arm is formed, is greater than an average line width of the main arm.

14. The light emitting device of claim 13, wherein the width of the extension portion is set to a range of 1.5 to 5 times of the average line width of the main arm.

15. The light emitting device of claim 13, wherein a top surface of the extension portion is shaped as one of a circle, an oval, a semicircle, a polygon, and a figure having a plurality of protrusions formed therein.

16. The light emitting device of claim 14, wherein a top surface of the extension portion is shaped as one of a circle, an oval, a semicircle, a polygon, and a figure having a plurality of protrusions formed therein.
